(19) United States
(12) Patent Application Publication
(10) Pub. No.: US 2011/0102009 A1
(43) Pub. Date: May 5, 2011

(54) TEST SOCKET ELECTRICAL CONNECTOR, AND METHOD FOR MANUFACTURING THE TEST SOCKET

(76) Inventor: Jae Hak Lee, Seoul (KR)

(21) Appl. No.: 13/000,166

(22) PCT Filed: Jun. 19, 2009
(86) PCT No.: PCT/KR2009/003292

§ 371 Date: Dec. 20, 2010

(30) Foreign Application Priority Data
Jun. 20, 2008 (KR) 10-2008-00058372

(51) Int. Cl. G01R 31/00; H01R 43/02

(52) U.S. Cl. 324/756.02; 324/756.05; 29/877

(57) ABSTRACT

A test socket, an electrical connector, and a method for manufacturing the test socket. In detail, the test socket for electrically connecting terminals of a semiconductor device to pads of a test apparatus includes: a housing having through-holes vertically extending to correspond in position to the terminals of the semiconductor device; contact pins disposed to correspond in position to the through-holes of the housing and contacting the terminals of the semiconductor device; and elastic members connected to the contact pins in the through-holes of the housing to contract and expand, wherein the elastic members are adhered to the contact pins by using an adhesive material.

### TECHNICAL FIELD

The present invention relates to a test socket, an electrical connector, and a method for manufacturing the test socket, and more particularly, to a test socket having excellent assemblability, excellent electrical characteristics, and a minute pitch, an electrical connection apparatus, and a method of fabricating the test socket.

### BACKGROUND ART A

In general, in order to test electrical characteristics of a semiconductor device, a stable electrical connection should be guaranteed between the semiconductor device and a test apparatus. In general, a test socket is used as a medium for connecting the semiconductor device to the test apparatus.

In detail, the test socket is disposed between terminals of the semiconductor device and pads of the test apparatus and electrically connects the terminals to the pads to exchange signals between them. To this end, pogo pins are used as contactors inside the test socket. Such pogo pins are each configured such that one pair of pins is disposed on upper and lower ends and a spring is disposed between the pair of pins. A plurality of the pins disposed on the upper ends contact the terminals and a plurality of the pins disposed on the lower ends contact the pads, the plurality of pins disposed on the upper ends and the plurality of pins disposed on the lower ends are electrically connected to each other, and a plurality of the springs absorb a mechanical impact that may occur when the pogo pins contact the terminals.

Referring to FIGS. 1 through 3, a conventional test socket 100 includes a housing 110 having through-holes 111 vertically formed therein to correspond in position to terminals 131 of a semiconductor device 130, and pogo pins 120 mounted in the through-holes 111 of the housing 110 and designed to electrically connect the terminals 131 of the semiconductor device to pads 141 of a test apparatus 140. Each of the pogo pins 120 includes a barrel 124 used as a pogo pin main body and having a hollow cylindrical shape, a contact tip 123 formed at a bottom of the barrel 124, a spring 122 connected to the contact tip 123 in the barrel 124 to contract and expand, and a contact pin 121 connected to a side of the spring 122 opposite to a side of the spring 122 connected to the contact tip 123 to vertically move as the pogo pins 120 contact the semiconductor device 130.

In this case, as the spring 122 absorbs a mechanical impact transmitted to the contact tip 123 and the contact pin 121 by contracting and expanding, the terminals 131 of the semiconductor device 130 and the pads 141 of the test apparatus 140 are electrically connected to each other and thus enable to test whether there is an electrical failure.

However, the conventional test socket 100 has the following problems.

First, since a signal applied from the pads 141 of the test apparatus 140 passes trough the contact tip 123, the spring 122, and the contact pin 121, and then is transmitted to the terminals 131 of the semiconductor device 130, a connection path is complex and particularly there are many contact points between elements, thereby leading to poor electrical connection characteristics.

Second, as products in which the semiconductor device 130 is to be installed are minimized, the semiconductor device 130 is minimized and the terminals 131 of the semiconductor device 130 have a minute pitch. In order to be smoothly connected to semiconductor device 130 having such a minute pitch, widths of the pogo pins 120 should be reduced. However, since minimum widths of the springs 122 are limited in order to maintain their mechanical characteristics and minimum thicknesses of the barrels 124 surrounding the springs 122 should be maintained in order to maintain their mechanical strengths, there is a limitation in reducing the widths of the pogo pins 120 of the conventional test socket 100. Accordingly, it is not easy to apply the pogo pins 120 to an up-to-date semiconductor device including terminals having a minute pitch.

Third, since the contact tip 123, the spring 122, and the contact pin 121 of the conventional test socket 100 are vertically connected to one another, an overall length between the contact tip 123 and the contact pin 121 is increased. Accordingly, there is a limitation in improving electrical characteristics.

### DETAILED DESCRIPTION OF THE INVENTION

### Technical Problem

The present invention provides a test socket which efficiently improves electrical connection characteristics by simplifying an electrical connection path, reduces widths of pogo pins by removing barrels surrounding springs, and improves electrical characteristics by reducing an overall length.

### Technical Solution

According to an aspect of the present invention, there is provided a test socket for electrically connecting terminals of a semiconductor device to pads of a test apparatus, the test socket including: a housing having through-holes vertically extending to correspond in position to the terminals of the semiconductor device; contact pins disposed to correspond in position to the through-holes of the housing and contacting the terminals of the semiconductor device; and elastic members connected to the contact pins in the through-holes of the housing to contract and expand, wherein the elastic members are adhered to the contact pins by using an adhesive material.

The adhesive material may be any one of a silver-tin (Ag—Sn) alloy, a gold-fin (Au—Sn) alloy, a silver-copper-tin (Ag—Cu—Sn) alloy, a silver-tin-bismuth (Ag—Sn—Bi) alloy, and a conductive resin, and the elastic members may be soldered by using the adhesive material.

The adhesive material may be a conductive resin including a synthetic resin and a plurality of conductive particles included in the synthetic resin.

The synthetic resin may include polyphenylene ether and a styrene-based resin.

The elastic members may be springs.

The elastic members may include conductive members each including an extending portion vertically extending and having a cross-section corresponding to an inner diameter of each of the springs and a protruding portion integrally formed with an upper end of the extending portion and having a cross-section greater than the cross-section of the extending portion, and the extending portions of the conductive members may be inserted into the springs and the protruding portions of the conductive members may be mounted on upper ends of the springs.

Metal layers may be plated on inner circumferential surfaces of the through-holes of the housing.

The metal layers may be formed of a precious metal such as gold or silver.

At least one of platinum (Pt), palladium (Pd), and rhodium (Rh) may be plated on surfaces of the metal layers.

According to another aspect of the present invention, there is provided an electrical connector disposed between first terminals and second terminals whose electrical connection is required, the electrical connection apparatus including: contact pins contactable with the first terminals; and springs having first ends connected to the contact pins and second ends connected to the second terminals to expand and contract thereon, wherein the contact pins are adhered to the springs by using an adhesive material.

The adhesive material may be any one of a silver-tin (Ag—Sn) alloy, a gold-tin (Au—Sn) alloy, a silver-copper-tin (Ag—Cu—Sn) alloy, a silver-tin-bismuth (Ag—Sn—Bi) alloy, and a conductive resin.

The conductive resin may include a synthetic resin and a plurality of conductive particles included in the synthetic resin.

According to another aspect of the present invention, there is provided a method of fabricating the test socket, the method including: fabricating contact pins having sharp first ends; plating an adhesive material on second ends of the contact pins; and electrically connecting springs to the contact pins by adhering the springs, which are aligned by a housing having through-holes formed therein to correspond in position to terminals of a semiconductor device, to the adhesive material.

The fabricating of the contact pins may include: generating grooves having wedge shapes in a substrate by using etching; depositing an oxide film on the substrate and patterning a photoresist (PR); and plating a conductive material, such as nickel-cobalt (Ni—Co) or nickel-tungsten (Ni—W), on the etched grooves.

The adhesive material may be a silver-tin (Au—Sn) alloy or a gold-tin (Au—Sn) alloy.

The adhering may include: heating the adhesive material to melt the adhesive material; inserting ends of the springs into the melted adhesive material; and cooling the adhesive material.

### ADVANTAGEOUS EFFECTS

According to the present invention constructed as described above, since contact pins are disposed at a bottom without barrels, an overall electrical connection path is simplified and thus electrical connection characteristics are improved.

Also, since barrels are removed, widths of pogo pins are reduced. Since contact pins are removed, an overall length is reduced, and thus electrical characteristics are improved.

### DESCRIPTION OF THE DRAWINGS

FIG. 1 is a cross-sectional view of a conventional test socket.

FIG. 2 is a cross-sectional view for explaining an operation of the conventional test socket of FIG. 1.

FIG. 3 is a cross-sectional view of a pogo pin used in the conventional test socket of FIG. 1.

FIG. 4 is a partial cross-sectional view illustrating major elements of a test apparatus according to an embodiment of the present invention.

FIG. 5 is an entire cross-sectional view of the test apparatus of FIG. 4.

FIG. 6 illustrates cross-sectional views for explaining a method of fabricating the test apparatus of FIG. 4.

FIG. 7 is a cross-sectional view of a test apparatus according to another embodiment of the present invention.

FIG. 8 is a cross-sectional view of a test apparatus according to another embodiment of the present invention.

### MODE OF THE INVENTION

The present invention will now be described more fully with reference to the accompanying drawings, in which exemplary embodiments of the invention are shown.

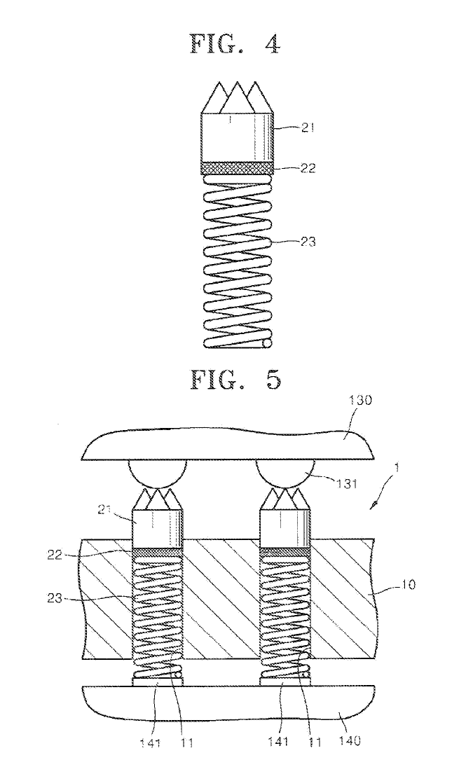

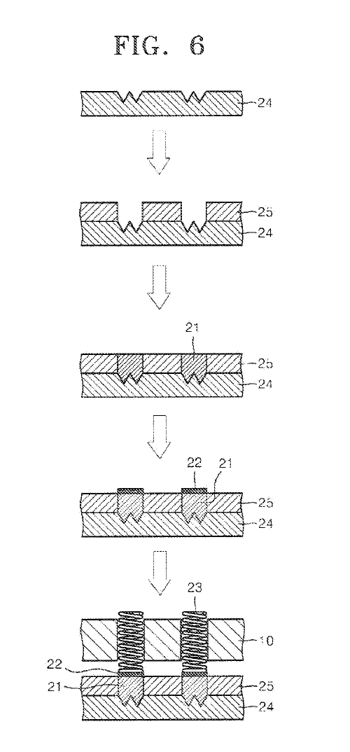

FIG. 4 is a partial cross-sectional view illustrating major elements of a test socket 1 according to an embodiment of the present invention. FIG. 5 is an entire cross-sectional view of the test socket 1 of FIG. 4. FIG. 6 illustrates cross-sectional views for explaining a method of fabricating the test socket 1 of FIG. 4.

Referring to FIGS. 4 through 6, the test socket 1 includes a housing 10, contact pins 21, an adhesive material 22, and elastic members.

The housing 10 formed of a synthetic resin is a unit for fixing the contact pins 21 and springs 23. Through-holes 11 vertically passing through the housing 10 are formed in the housing 10 to correspond in position to terminals 131 of a semiconductor device 130.

The contact pins 21 are disposed to correspond in position to the terminals 131 of the semiconductor device 130, and contact the terminals 131 of the semiconductor device 130. In detail, the contact pins 21 may be fabricated by using a microelectromechanical system (MEMS), but the present embodiment is not limited thereto. Four quadrangular pyramids are formed on an upper end of each of the contact pins 21, in order to increase a contact force with each of the terminals 131 of the semiconductor device 130. However, a shape of the upper end of each of the contact pins 21 is not limited thereto, and may be any of various shapes such as a single pyramid or cone.

The adhesive material 22 adheres the elastic members to the contact pins 21. In detail, the adhesive material 22 is formed on portions of the contact pins 21 opposite to portions of the contact pins 21 contacting the terminals 131 of the semiconductor device 130. The adhesive material 22 may be a conductive resin or a soldering material such as a silver-tin (Au—Sn) alloy or a gold-tin (Au—Sn) alloy. However, the soldering material is not limited thereto, and may be any of various environment-friendly materials other than lead. The conductive resin includes a synthetic resin and a plurality of conductive particles included in the synthetic resin. The synthetic resin may be a composite resin including polyphenylene ether and a styrene-based resin in order to improve adhesion and stability, but may be any of various synthetic resins. Also, the conductive particles may be powder particles such as nickel, silver, or carbon nanotubes (CNTs) having high conductivity, and a plating layer may be formed on surfaces of the powder particles.

The elastic members are connected to the contact pins 21 in the through-holes 11 of the housing 10, to contract or expand. In detail, the elastic members provide an elastic force to the contact pins 21 so that the contact pins 21 may vertically move. In the present embodiment, the elastic members include the springs 23. The springs 23 have lower ends contacting pads 141 of a test apparatus 140. Also, upper ends of the springs 23 are electrically and mechanically connected to the contact pins 21 by the adhesive material 22.

A method for manufacturing the test socket 1, according to an embodiment of the present invention, will now be explained.

First, the contact pins 21 are fabricated by using a MEMS. The contact pins 21 have sharp first ends contacting the terminals 131 of the semiconductor device 130. In detail, the contact pins 21 are formed by forming grooves having wedge shapes in a substrate by wet etching, depositing an oxide film on the substrate, patterning a photoresist (PR), and plating a conductive material, such as nickel-cobalt (Ni—Co) or nickel-tungsten (Ni—W), on the etched grooves.

Next, the adhesive material 22 is plated on second ends of the contact pins 21. The adhesive material 22 is a Ag—Sn alloy or a Au—Sn alloy. Although the adhesive material 22 is plated on the second ends of the contact pins 21 by using a plating process, the adhesive material 22 may be subjected to various processes.

Next, the springs 23 which are elastic members aligned by the housing 10 having the through-holes 11 formed therein to correspond in position to the terminals 131 of the semiconductor device 130 are adhered to the adhesive material 22, to electrically connect the springs 23 to the contact pins 21. In detail, after the adhesive material 22 is heated by a predetermined heater to melt, ends of the spring 23 aligned by the housing 10 are dipped into the melted adhesive material 22, and the adhesive material 22 is cooled, thereby completely fabricating the test socket 1.

The test socket 1 according to the present embodiment has the following effects.

In order to test the semiconductor device 130, the test socket 1 is mounted on the test apparatus 140. Lower ends of the springs of the test socket 1 are brought into contact with the pads 141 of the test apparatus 140. Next, the semiconductor device 130 is lowered, so that the terminals 131 of the semiconductor device 130 contact upper ends of the contact pins 21, respectively. When the terminals 131 are further lowered, the springs 23 compress to absorb a mechanical impact. If a signal is applied from the test apparatus 140 after, the signal passes through the pads 141 of the test apparatus 140, the springs 23, and the contact pins 21, and then reaches the terminals 131 of the semiconductor device 130, or passes through the springs 23, metal layers, and the contact pins 21, and reaches the semiconductor device 130. As such, since the test socket 1 has a short electrical connection path, a stable electrical connection is achieved.

Also, while contact pins, springs, contact tips, and barrels are all needed in a conventional test socket, since only the contact pins 21 and the springs 23 are needed in the test socket 1 to achieve an electrical connection, the number of parts is reduced, manufacturability is improved, and manufacturing costs are reduced.

Also, since the barrels and the springs are all used in the conventional test socket, there is a limit in reducing an overall width spatially. However, since no barrel is used in the present embodiment, an overall width is dependent on only the springs 23, and thus the test socket 1 may be applied to a device having a minute pitch.

Also, since the contact pins 21 of the test socket 1 of the present embodiment are fabricated by using a MEMS, shapes of the contact pins 21 may be easily changed for use on various devices.

Also, since the contact pins 21 of the test socket 1 of the present embodiment are fabricated by using silicon wet etching, constant inclined surfaces (54.7 degrees) may be obtained according to a crystal direction, thereby reducing friction and contamination during contact with the terminals 131 of the semiconductor device 130.

Also, since the adhesive material 22 of the test socket 1 of the present embodiment is not coated by using a separate process but is plated together when the contact pins 21 are fabricated, an overall manufacturing process is facilitated.

Although the test socket 1 for connecting the semiconductor device 130 to the test apparatus 140 is constructed as described above, the test socket 1 may have other structures as follows.

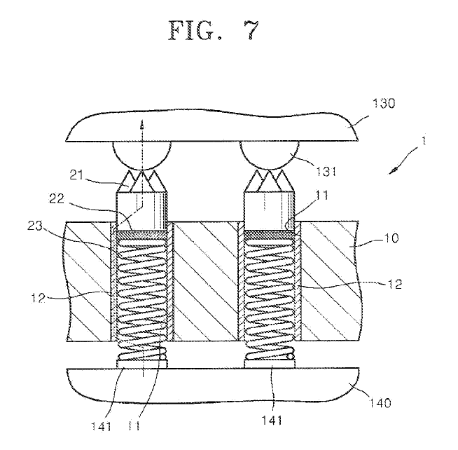

First, while additional plating layers are not formed in the through-holes 11 of the housing 10 in FIG. 5, metal layers 12 may be plated on inner circumferential surfaces of the through-holes 11 of the housing 10 to extend from upper ends to lower ends as shown in FIG. 7. That is, the metal layers 12 attached to the inner circumferential surfaces of the through-holes 11 are plating layers formed of a precious metal, such as Au or Ag to increase conductivity. In order to increase the strength of the Au or Ag, metal layers formed of platinum, rhodium, or palladium may be plated on surfaces of the metal layers 12 formed of a material having high conductivity such as Au or Ag. As such, as the metal layers 12 are formed on the inner circumferential surfaces of the through-holes 11, conductivity is increased and strength is also increased.

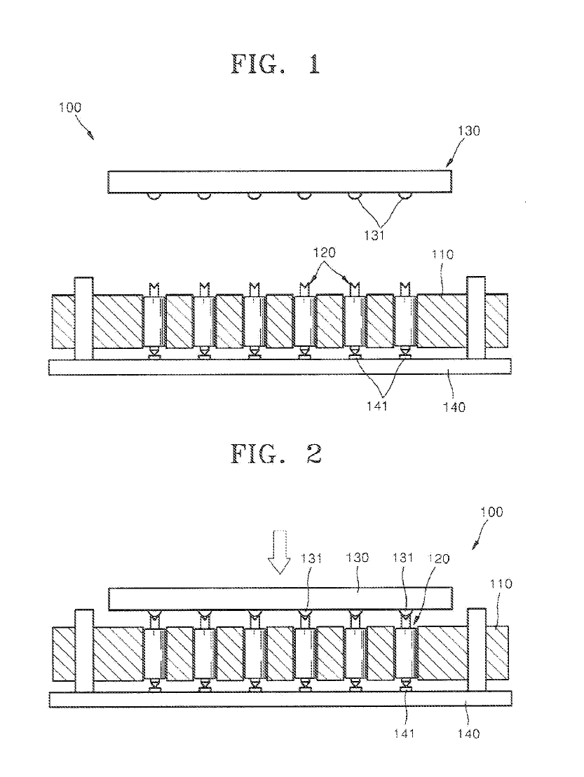

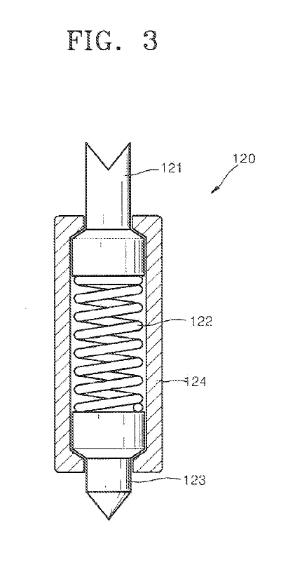

The metal layers 12 help to achieve a fast electrical connection overall. That is, springs 122 of the conventional test socket 100 in FIG. 1 reduce a mechanical impact and electrically connect contact pins 121 to contact tips 123. In this case, a signal transmitted from pads 141 of the test apparatus 140 is helically transferred through the springs 122. Accordingly, an electrical connection path is lengthened, and if the signal is a high frequency signal, the signal may not be stably transmitted through the springs 122. However, in the present embodiment, as indicated by an arrow of FIG. 7, a signal applied from the pads 141 of the test apparatus 140 passes through the springs 23 and the metal layers 12 and is transmitted to the contact pins 21 which are disposed at upper ends, thereby reducing an overall electrical connection path and improving overall electrical connection characteristics.

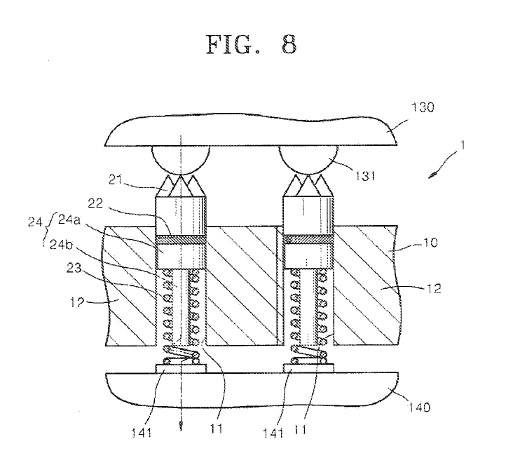

Second, while only the springs 122 are elastic members in FIG. 5, conductive members 24 may be further provided as shown in FIG. 8. The conductive members 24 each include a protruding portion 24a and an extending portion 24b. A plurality of the extending portions 24b are inserted into the springs 23, and a plurality of the protruding portions 24a are mounted on upper ends of the springs 23. The extending portions 24b having cross-sectional shapes enough to be inserted into the springs 23 may have circular cross-sections substantially conforming to inner diameters of the springs 23. The protruding portions 24a have cross-sections greater than the inner diameters of the springs 23 in order to be mounted on the upper ends of the springs 23. In this case, the adhesive material 22 is disposed between the contact pins 21 and upper ends of the protruding portions 24a. As such, when the conductive members 24 are further provided, an electrical connection path is simplified and shortened. That is, as shown in FIG. 8, a signal is not transmitted along the springs 23, but transmitted through the conductive members 24. However, a signal may be transmitted through the springs 23 at places where the conductive members 24 do not contact the pads 141 of the test apparatus 140, such as at lower ends of the springs 23.

Third, although the afore-described test socket 1 is used only to connect the semiconductor device 130 to the test apparatus 140, the test socket 1 may be used as an electrical connector disposed between first terminals and second terminals for which electrical connection is required. In this case, the electrical connector includes contact pins which may contact the first terminals, and springs having first ends connected to the contact pins and second ends electrically connected to the second terminals to expand and contract thereon, wherein the contact pins are adhered to the springs by using an adhesive material. In this case, the adhesive material may be any one of a Ag—Sn alloy, a Au—Sn alloy, a Ag—Cu—Sn alloy, a Ag—Sn—Bi alloy, and a conductive resin. Also, the conductive resin includes a synthetic resin and a plurality of conductive particles included in the synthetic resin.

Also, predetermined protrusions may further formed on the inner circumferential surfaces of the through-holes 11.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A test socket for electrically connecting terminals of a semiconductor device to pads of a test apparatus, the test socket comprising:
a housing having through-holes vertically extending to correspond in position to the terminals of the semiconductor device;
contact pins disposed to correspond in position to the through-holes of the housing and contacting the terminals of the semiconductor device; and
elastic members connected to the contact pins in the through-holes of the housing to contract and expand,
wherein the elastic members are adhered to the contact pins by using an adhesive material.

2. The test socket of claim 1, wherein the adhesive material is any one of a silver-tin (Ag—Sn) alloy, a gold-tin (Au—Sn) alloy, a silver-copper-tin (Ag—Cu—Sn) alloy, a silver-tin-bismuth (Ag—Sn—Bi) alloy, and a conductive resin, and the elastic members are soldered by using the adhesive material.

3. The test socket of claim 1, wherein the adhesive material is a conductive resin comprising a synthetic resin and a plurality of conductive particles included in the synthetic resin.

4. The test socket of claim 3, wherein the synthetic resin comprises polyphenyiene ether and a styrene-based resin.

5. The test socket of claim 1, wherein the elastic members comprise springs.

6. The test socket of claim 5, wherein the elastic members comprise conductive members each comprising an extending portion vertically extending and having a cross-section corresponding to an inner diameter of each of the springs and a protruding portion integrally formed with an upper end of the extending portion and having a cross-section greater than the cross-section of the extending portion, and the extending portions of the conductive members are inserted into the springs and the protruding portions of the conductive members are mounted on upper ends of the springs.

7. The test socket of claim 1, wherein metal layers are plated on inner circumferential surfaces of the through-holes of the housing.

8. The test socket of claim 7, wherein the metal layers comprise a precious metal such as gold or silver.

9. The test socket of claim 7, wherein at least one of platinum (Pt), palladium (Pd), and rhodium (Rh) is plated on surfaces of the metal layers.

10. An electrical connector disposed between first terminals and second terminals for which electrical connection is required, the electrical connection apparatus comprising:
contact pins contactable with the first terminals; and
springs having first ends connected to the contact pins and second ends connected to the second terminal to contract and expand thereon,
wherein the contact pins are adhered to the springs by using an adhesive material.

11. The electrical connector apparatus of claim 10, wherein the adhesive material is any one of a silver-tin (Ag—Sn) alloy, a gold-tin (Au—Sn) alloy, a silver-copper-tin (Ag—Cu—Sn) alloy, a silver-tin-bismuth (Ag—Sn—Bi) alloy, and a conductive resin.

12. The electrical connector of claim 11, wherein the conductive resin comprises a synthetic resin and a plurality of conductive particles included in the synthetic resin.

13. A method for manufacturing the test socket of claim 1, the method comprising:
fabricating contact pins having sharp first ends;
plating an adhesive material on second ends of the contact pins; and
electrically connecting springs to the contact pins by adhering the springs, which are aligned by a housing having through-holes formed therein to correspond in position to terminals of a semiconductor device, to the adhesive material.

14. The method of claim 13, wherein the fabricating of the contact pins comprises:
forming grooves having wedge shapes in a substrate by using etching;
depositing an oxide film on the substrate and patterning a photoresist (PR); and
plating a conductive material, such as nickel-cobalt (Ni—Co) or nickel-tungsten (Ni—W), on the etched grooves.

15. The method of claim 13, wherein the adhesive material comprises a silver-tin (Au—Sn) alloy or a gold-tin (Au—Sn) alloy.

16. The method of claim 13, wherein the adhering comprises:
heating the adhesive material to melt the adhesive material;
inserting ends of the springs into the melted adhesive material; and
cooling the adhesive material.
